(19) United States
(12) Patent Application Publication
(10) Pub. No.: US 2006/0041798 A1
(43) Pub. Date: Feb. 23, 2006

(54) Design techniques to increase testing efficiency

(75) Inventor: Laurence H. Cooke, Los Gatos, CA (US)

Correspondence Address: VENABLE LLP, P.O. BOX 34385, WASHINGTON, DC, 20045-9998, US

(73) Assignee: On-Chip Technologies, Inc., Los Gatos, CA (US)

(21) Appl. No.: 10/922,830

(22) Filed: Aug. 23, 2004

(51) Int. Cl. G11C 29/00

(52) U.S. Cl. 714/718

(57) ABSTRACT

Specific test logic may be added into a semiconductor logic or memory device, which does not change the normal operation of the device, but which allows under test mode the device to perform both parallel read-compare and parallel write operations of the blocks within the device, which provides significant reduction of the overall time to test the device.

### FIELD OF THE INVENTION

The present invention reduces logic or memory test time by adding test structures specifically designed to reduce the number of operations necessary to functionally test semiconductor logic or memories.

### BACKGROUND OF THE INVENTION

Semiconductor memories such as shown in FIG. 2, consist of address decoders 27, sense/drive logic 21 controlled by a write enable line 22, bi-directional I/O 23 controlled by a Read enable signal 24 and a memory core 25, consisting of an array of memory bits as shown in FIG. 3a. The bits are read or written by turning on word lines 30 from the address decoder. The resulting data is set on or received from the bit lines 31 connected to each memory cell. Whether the memory cells 32 are single transistor DRAM cells 32 or SRAM cells 33, one of which is shown in FIG. 3b, the devices currently being built contain close to a billion of these cells. Testing such large memories is now becoming a time consuming and costly part of manufacturing.

When testing semiconductor memory, the primary motivation is to test all common failure mechanisms in the memory including:
single and multiple bit failures to store data,
adjacent memory bit shorts,
bit line shorts and opens, and
various types of addressing failures.

This is generally accomplished by some combination of the following:
writing each cell to a value different from its surroundings,
reading them back,
writing all cells to their opposite values,
reading them back,
writing selected addressed cells differently,
reading them back in a different order

All of these steps requires at least on the order of N tests, where N is the number of addresses in the memory. Some of the quickest algorithms are ˜7N read and write cycles. As a consequence of such long tests, a number of techniques have been developed in recent years to reduce the memory test cost, memory test time or both. Some employ improvements in the testers to speed up testing or test multiple parts simultaneously such as Kobayashi in U.S. Pat. No. 6,523,143. These reduce the test cost but do not appreciably speed up the testing of a single part. Built-in test logic has also been developed to both speed up the generation of tests and reduce the test data output such as stated by Hedberg et al., in U.S. Pat. No. 6,026,505, issued Feb. 15, 2000, but again they do not reduce the test time. Kim in U.S. Pat. No. 6,338,154, issued Jan. 8, 2003, and Pierce et al. in U.S. Pat. No. 5,033,048, issued Jul. 16, 1991, both claim improved performance using different types of Built-in self test (BIST) logic on the chip and external to the chip, respectively. Still, they are not reducing the number of test clock cycles for the actual memory, rather they seem to be reducing the data required for testing.

In the last 30 years the size of memory has doubled every 18 months, and this trend does not appear to be stopping soon, so while all of these techniques reduce the test cost in one fashion or another, none of the above techniques actually tackles the problem of reducing the time in accessing the memory core during test. Still, there have been some efforts to reduce the actual test time, but they have been limited at best. Nakashima, in U.S. Pat. No. 5,896,333, issued Apr. 20, 1999 describes speeding up the clocking of the tests, which should provide some limited improvement. Wang, in U.S. Pat. No. 6,543,015, issued Apr. 1, 2003, implies some form of parallel testing, but is not specific about what test reduction is achieved from his address compression, beyond merely reducing the amount of output.

### SUMMARY OF THE INVENTION

The current invention is a set of techniques to add test logic in the address decoders and read/write data registers to test the memory in much less than N cycles. This is accomplished by:
a. Adding a test-mode register for distinguishing between test and normal operation.
b. Modifying the decoder to address more than one word at a time, and
c. Modifying the read/write data registers to compare all of them simultaneously.

With the proposed test logic additions the tests in test mode are then:
a. Write blocks of data in parallel,
b. Read blocks of data into read/write data registers in parallel,
c. Compare all read results with external data simultaneously, and
d. Output the results of the comparison only.

Given the state of the memory at the end of the test mode tests, testing the address logic, which can be done in O(logN) tests, is short enough to complete in normal mode.

The use of these techniques can reduce the number of write cycles to a handful, regardless of the size of memory, and reduce the read cycles down to the ratio of the size of the memory to the size of the read/write data registers, which can be as much as two or three orders of magnitude improvement. The combination will reduce test time down to a fraction of what is currently done, by dramatically reducing the number of read/write cycles necessary to complete the tests.

The design technique includes a way to test without changing the pins or the normal function of the memory. This can be accomplished by setting the test mode during power-up, resettable by a particular configuration of address bits.

The bulk of tests, to be done in test mode, generally require different configurations of at least 4 bits. For memories that have less than 4 data pins, the address pins can double as data during the parallel test.

In addition, while focusing primarily on memories, in large integrated chips today, logic blocks appear to the overall system like sub-blocks of memory connected by a bus. Like memories, they are separately addressed, written into and read from, by a master block on the bus. As such, the same principles applied to accelerate the testing of memories can be applied to accelerate testing of these logic blocks with their associated bus.

Finally, these techniques can be extended to any serially addressed structure, which by suitable transformation under test can accelerate testing by accessing the logic in parallel.

### BRIEF DESCRIPTION OF THE DRAWINGS

The invention will now be described in connection with the attached drawings, in which:

FIG. 1 is a high-level architectural diagram of a large memory,

FIG. 2 is a high level diagram of a small example memory core,

FIG. 3a is a more detailed diagram of the memory core in FIG. 2,

FIG. 3b is an alternative memory cell for the cells in FIG. 3a,

FIG. 4 is a high level diagram of a memory with fewer data I/O than bit lines,

FIG. 5 is a more detailed diagram of the register and I/O logic in FIG. 4,

FIG. 6 is a more detailed diagram of the address decode logic in FIG. 4,

FIG. 7 is a more detailed diagram of the Read/Write register logic in FIG. 5,

FIG. 8 is a more detailed diagram of the decode logic in FIG. 5,

FIG. 9 is a diagram of the test mode storage bit,

FIG. 10 is a diagram of the logic in FIG. 7 modified for testing,

FIG. 11 is a diagram of the logic in FIG. 6 modified for testing,

FIG. 12 is a diagram of the logic in FIG. 5 modified for testing,

FIG. 13 is a more detailed diagram of the MUX logic in FIG. 12,

FIG. 14 is a more detailed diagram of the decode logic in FIG. 12,

FIG. 15 is a four-bit alternative to the logic in FIG. 5 modified for testing,

FIG. 16 is a more detailed diagram of the decode logic in FIG. 15,

FIG. 17 is a diagram of multiple memories connected together,

FIG. 18 is a more detailed diagram of one possible tristate driver that may be used in FIG. 12,

FIG. 19 is a diagram of a MUX with a decoder,

FIG. 20 is a diagram of multiple logic blocks connected to a bus,

FIG. 21 is a diagram of multiple logic blocks connected to a common output,

FIG. 22 is a diagram of the decode logic within a logic block shown in FIG. 21,

FIG. 23 is a diagram of the decode logic within FIG. 22 with test logic added, and

FIG. 24 is a diagram of the decode logic within FIG. 23 with comparison logic added.

### DESCRIPTION OF VARIOUS EMBODIMENTS

In one embodiment of the invention, test logic is added to the design of a memory block, tests are generated taking into consideration the structure of the test logic and executed on a die during wafer test, executed on final packaged parts during final test and possibly executed within customer products, without affecting the pins or normal operation of the memory block. These techniques can be best described by a series of examples as follows.

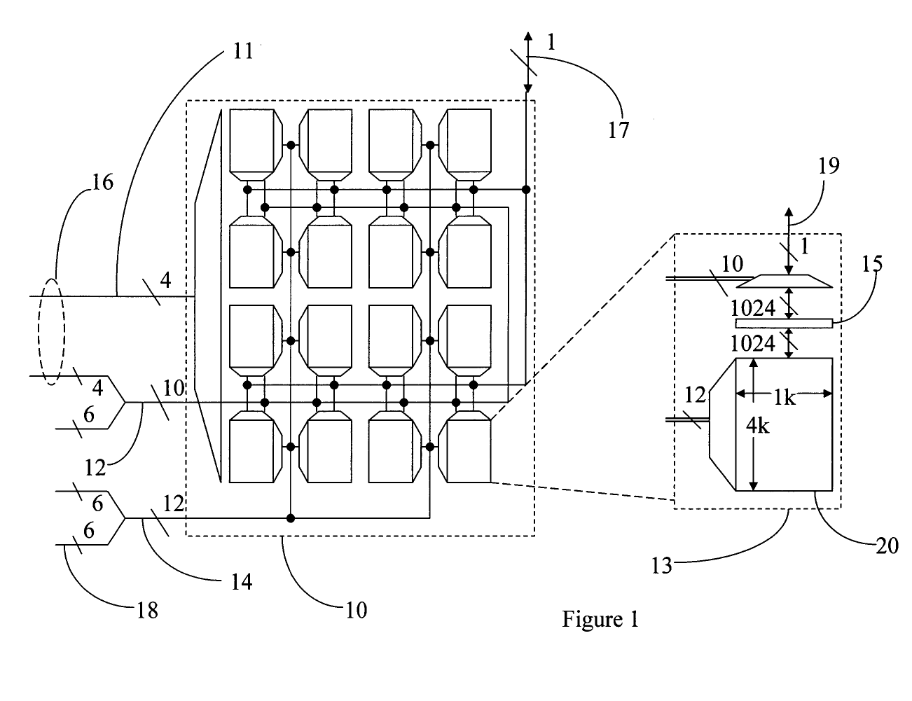

For a first example as shown in FIG. 1, a 1 by 64 Mb memory 10 may be comprised of sixteen 4 Mb memory sub-blocks each of which is organized as 4K deep by 1K wide, as shown in FIG. 1. In this case there are sixteen memory sub-blocks 13, one of which is enabled at any given time, by the top four address bits 11. The next ten address bits 12 choose which of the 1K bits out of each memory sub-block's core 20 to select, and the last twelve address bits 14 choose the word in each of the memory sub-blocks 13. Such a memory would consist of sixteen read-modify-write memory sub-blocks 13, where the data is read out of the enabled core 20 into the 1K wide registers 15, the bit being changed is written into the register 15, which is then written back into the core 20.

In another embodiment, the memory 10 can be put into test mode by powering up the device with its enable at a high level during power-up to preset a test bit and place the device into test mode. When configured in the test mode, the top fourteen bits of the address are employed as test pins. During write operations, in the test mode, the top eight address bits 16 are used to contain data values which are written repeatedly into the 128 consecutive eight bit positions of the register 15. If the memory is packaged as an 8 by 8 Mb memory, the data pins 17 can be used to provide the eight bit data values applied to the top eight address bits 16 which are written into the register 15 of each sub-block 13.

The pattern written into the register, is in turn written, on each write operation, into every sixty-fourth position of all sixteen memory cores 20 simultaneously, the specific locations determined by an address formed by the last six address bits 18 of the lower twelve bits of the address 14 to the cores 20. This requires only sixty-four write operations to fill the entire memory. During a read operation in the test mode data is read back in sequence from each 4096 words of each of the sixteen memory cores 20, while accessing the memory sub-blocks 13 in parallel. For each read operation, 1024 bits are read from each memory core 20 and compared with present values in the corresponding 1024 bit register 15. If all bits match the written data, the single bit data out 19 is set to logic 0, otherwise it is set to logic 1. Finally, the one bit output values 19 are gated together, using wired-logic, or other discrete logic, to form a composite output signal 17 to indicate if any of the bit-wise comparisons have a mismatch. On the other hand, if the memory 10 is packaged as an 8 by 8 Mb memory, each memory sub-block 13 would output eight bits, which are wire-ORed with the other fifteen sub-blocks' outputs, and the results from 256 separate sets of compared data can be combined and output together for each read operation.

The structure for a 1 by 64 MB memory, exemplified above, reduces the total number of write cycles needed to write data into all bit positions by a factor of 1,048,576 (i.e., 1M) while reducing the number of read (and compare) cycles out of all bit positions by a factor of 16,384 (i.e., 16K). In other words, the entire memory can be read in 4K cycles, and the entire memory can be written in 64 cycles.

Typically test patterns may stop early if a flaw in the memory is detected, but for a part with no flaws it will continue to completion. Under these conditions, for a part with no flaws, if a normal test pattern takes 14N where N is 64 Mb, or 939,524,096 cycles, the new test takes 924,672 cycles for a part with no flaws, so if the memory test is run at 25 million cycles per second, the test would take 37.6 seconds for the normal part, as compared to 0.03 seconds for the same part under the test mode described in this invention.

Now to minimize the impact of the test logic and the performance overhead for the test, the following is done:

When writing:

The top six bits override the low order address bits, and the rest of the address bits drive the partial decode. This is done by ANDing the test bit into the inverters of upper order address bits (which should be set to all 1s to select multiple lines).

When reading:

For each register bit, for each memory structure XOR the memory being read and register bit. OR all of these bits together and output the results.

This technique will write and read at some multiples of the normal operation, but the multiple is limited by power consumption. As much as half the memory can be written at one time, or as little as 1/2ⁿ where n is some number less than m: the total memory address size. Clearly if m-n=1 then only two lines are written at the same time, which is not significant power consumption but not much compression, either; on the other hand, if ½ the memory is written, driving the additional capacitance of ½ the memory cells turned on to their bit line may take considerably more power and/or time to successfully write all the cells. Under such conditions two options are available for tuning the test time and test logic:

1) Lengthen the Write cycle to maximize the testing time. In other words Maximize[#parallel writes/required testing frequency];

2) Improve the power grid and bit line amplifier design to improve the write frequency.

For the purposes of illustration of the techniques defined above, a much smaller example is shown in the subsequent Figures.

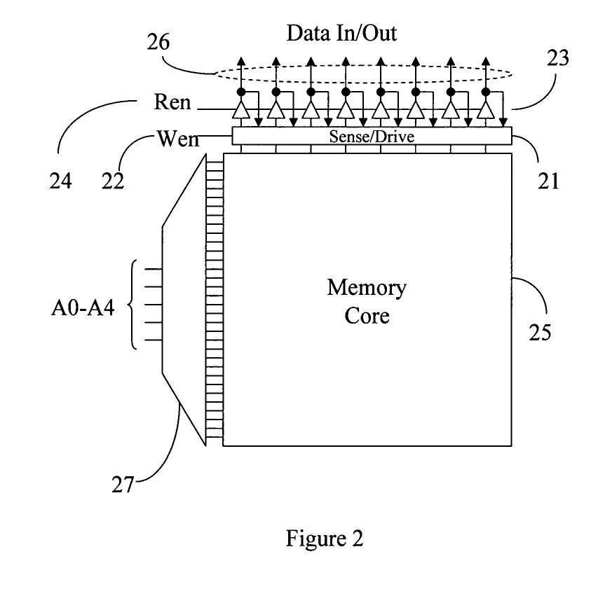

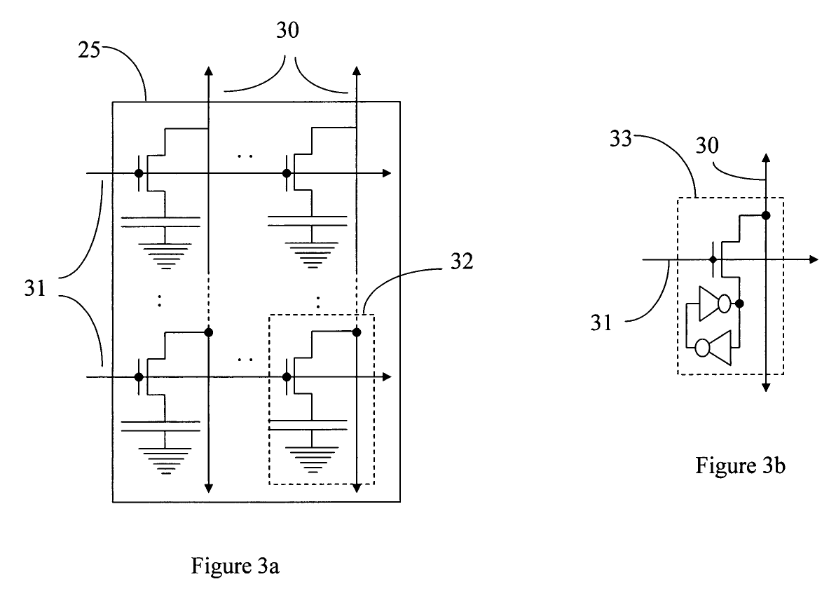

FIG. 2 is a diagram of a typical memory consisting of an address decoder 27, a set of sense/drive logic 21 controlled for read or write by a Write enable signal 22, a set of bi-directional buffers 23 whose tristate output drivers are controlled by a read enable signal 24, and a memory core 25, shown in FIG. 3a, consisting of a multiplicity of memory cells 32, accessed by a multiplicity of word lines 31, resulting in either reading or writing a row of memory cells data from or onto the respective multiplicity of bit lines 30 they are connected to. The memory cell 32 shown in FIG. 3a is typical of those cells found in DRAMs. Alternatively, the memory core 25 could be filled with memory cells typically found in SRAMs, as shown in FIG. 3b. The memory shown in FIG. 2 has as many Data In/Out pins 16 as bit lines 30 in the memory core 25, shown in FIG. 3a.

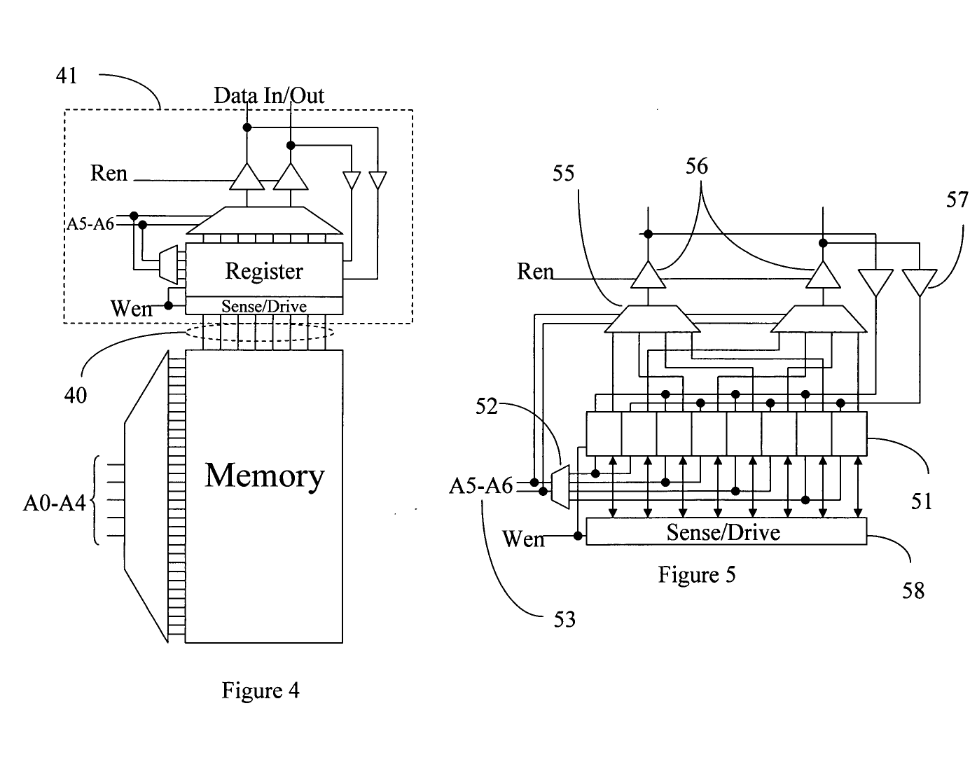

Typically, in large memories today, performance dictates that the memory have many more bit lines than Data In/Out lines. FIG. 4 shows an example of a memory with eight bit lines 40 and encode/decode logic down to two bits of Data In/Out. FIG. 5 is a more detailed diagram of encode/decode logic shown in FIG. 4. Typically, the encode/decode logic includes some high order bits of the address 53, which select, via a MUX 55, the proper bit values to output to the tristate buffers 56, which are turned on for a read operation. A write operation must be careful to correctly write only the new information being inputted. This is done by reading all the memory bits in the row of memory bits selected by one specific word line into a bank of registers 51, and then enabling only specific registers via a decoder 52, to write new data in, from the input buffers. The contents of all the registers are then re-written into the word line selected memory cells by the sense/drive logic 58.

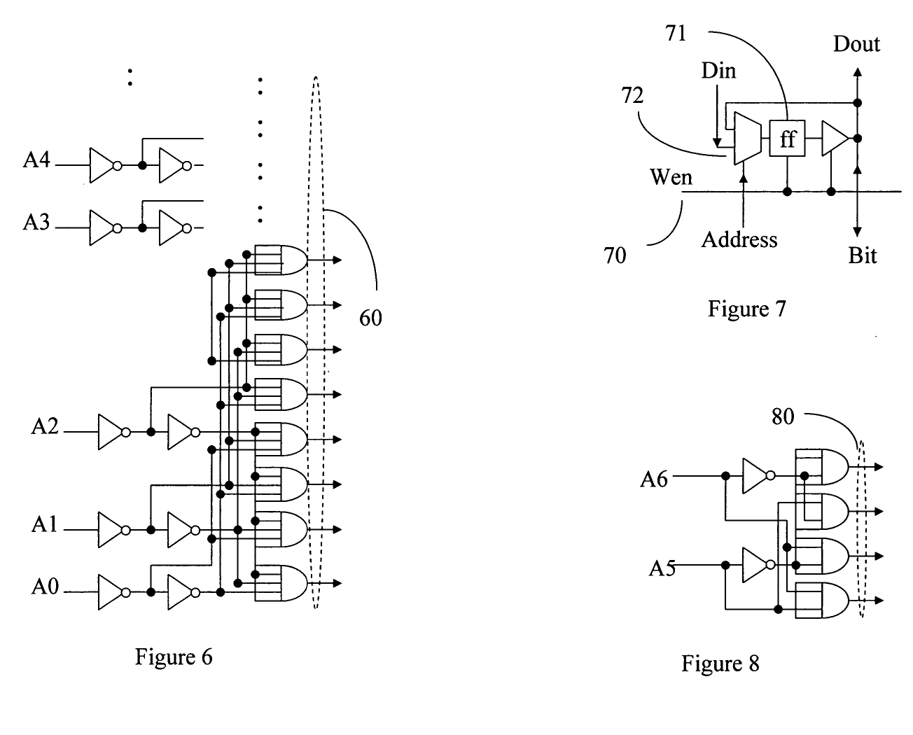

FIG. 6 shows a portion of the details of the address decoder 27 shown in FIG. 2.

FIG. 8 shows the details of the decoder 52 in FIG. 5. In each case, only one of the set of decoder outputs 60, 80 is on at a time. FIG. 7 shows one embodiment of the detailed logic of one of the registers 51 shown in FIG. 5. In this embodiment the write enable acts as a clock to capture the data into the flip-flop 71. One of the address decoder outputs 60 in FIG. 6, controls the MUX 72 to select between the Data in and the data from the selected word in the memory.

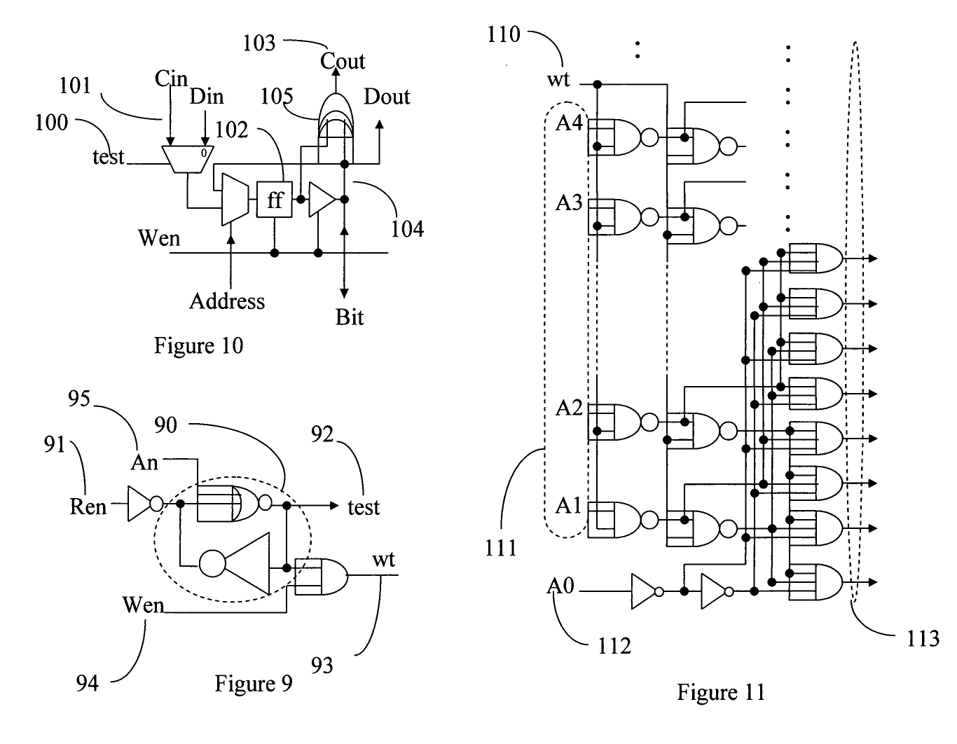

In an embodiment of the invention, a memory chip or block such as described in FIGS. 2 through 8, has the same external logic pins and functionality in its normal mode of operation, but can be put into test mode while powering up the device, to minimize the test time. FIG. 9 shows one embodiment of logic to achieve this. During normal power-up the Ren 91 signal is held Low. This forces the latch 90 to come up in a state where test 92 is low, and the write test signal wt 93 is also low. These control signals can then be used to insure the device is in normal operation. Conversely, if the Ren 91 signal is brought up with the power supply and a high order address bit An 95 is held low, the latch 90 will come up with test 92 set high, and wt 93 will be set to the same value as Wen 94.

Without powering down the normal state can be invoked by setting the An 95 line high, after which, the part can only be put in test mode by powering down and back up.

Now the test logic is as follows: FIG. 10 is a diagram of the register logic in FIG. 7 modified for testing. In test mode the test signal 100 selects the Cin 101 signal to be captured by the flip-flop 102. The Cout 103 signal is the exclusive-OR of the Flip-flop 102 value and the value on the bit line 104. In this way during a read the contents of the flip-flop are compared with the contents from the word being addressed.

FIG. 11 is a diagram of the address decode logic in FIG. 6 modified for testing. When the device is in test mode, the wt 110 signal overrides both phases of the upper order address bits 111, turning on all the word lines 112 associated with the decoded values of the lower order addresses 113. In this case ½ of the word lines are accessed at a time.

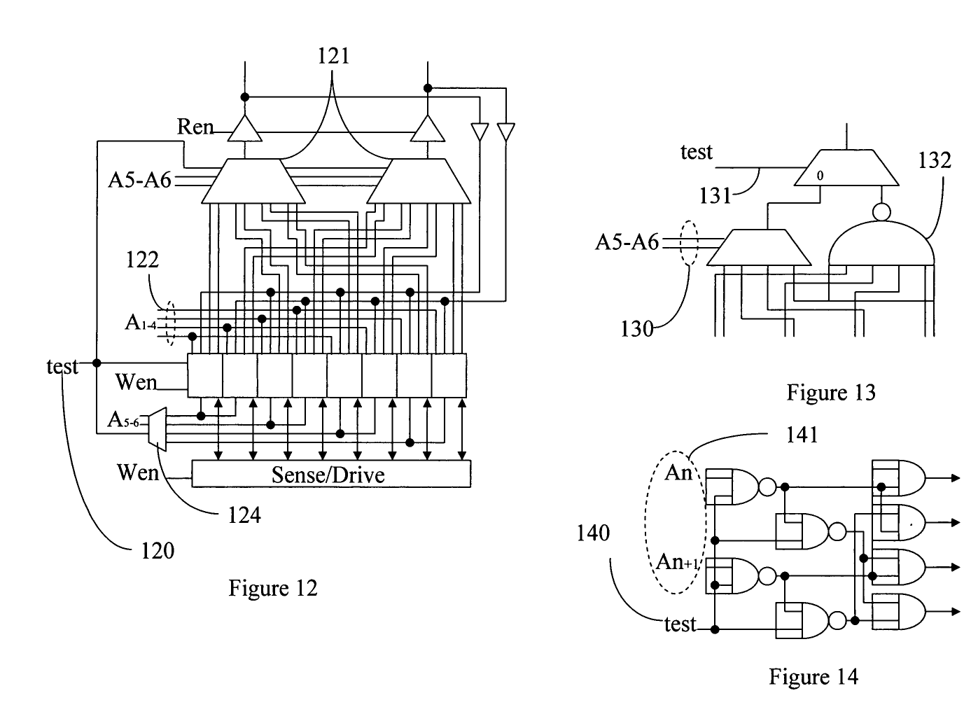

FIG. 12 is a diagram of the logic in FIG. 5 modified for testing. The test 120 signal is applied to the MUX and decode logic, whose details can be seen in FIGS. 13 and 14. Some of the address bits 111 in FIG. 11 are used to input data 122 into the registers, and are selected by the test signal 100 in FIG. 10 to be loaded into the flip-flop 102. Furthermore, both Cout 103 and Dout 104 are inputs to the MUX function 121.

FIG. 13 is a more detailed diagram of the MUX logic 121 in FIG. 12. In normal mode the Address bits A5 and A6 130 select between the Dout data. During test mode the test signal 131 selects the NAND gate, which combines the comparison data for all for bits.

FIG. 14 is a more detailed diagram of the decode logic 124 in FIG. 12. Test 140 overrides the address decoder, enabling all registers to be written during a write. Since the address bits An and An+1 141 are not being used, either can serve as the An address bit 94 for the test mode logic in FIG. 9. From these test logic additions, the writes occur simultaneously, in this case for ½ of the memory at a time.

From the test logic described above it should be clear that the values on the A1-4 address bits are loaded in a repeating pattern into the registers during a write. During a read the contents of the last write are compared with the word being read. If the contents are exactly the opposite of the data being read, all values out of the exclusive-ORs 105 in FIG. 10 are high. These in turn set the NAND gate 132 in FIG. 13 low. Now typically testing memories consists of writing a repeating pattern into even addresses and then writing the opposite pattern into odd addresses, and reading the original even addressed values back. In this 2 wide 128 bit deep memory example the pattern can be written in 2 cycles, ½ of the memory can be read back in 16 cycles and the other half takes 1 more write and 16 more reads, as compared to 128 write cycles and 128 read cycles for a memory without the test logic, a savings of 221 cycles.

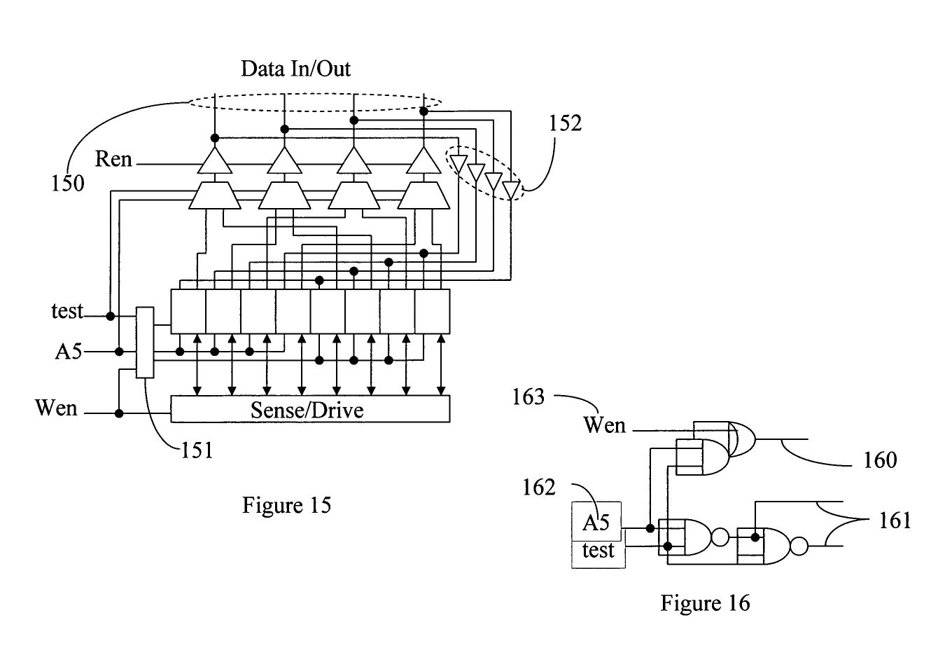

In another embodiment, if the memory configuration has sufficient Data In/Out pins, typically at least four, the Data In/Out pins can put the repeating values into the registers without having to use the address lines. FIG. 15 shows such a structure with test logic. In this case there are four Data In/Out lines 150. The address decoder and register clock logic 151 are shown in greater detail in FIG. 16. In test mode A5 162 is blocked by test 163, which drives all decoded outputs 161 high, thus enabling all register bits to capture a repeating set of values from the input buffers 152 seen in FIG. 15. The clock 160 in FIG. 16 in normal mode is Wen, the same Wen 70 as seen in FIG. 7, but in test mode A5 162 is ORed with Wen 163. This allows additional test savings because A5 can be used to clock in the expected read values without a write operation, but A5 cannot be the An 94 shown in FIG. 9, which must remain low to stay in test mode. Clearly, this particular clock enhancement, though shown here, is only applicable when two or more decoder address bits and 4 or more data In/Out bits occur in the original memory design, unless the design is hierarchical as is explained below.

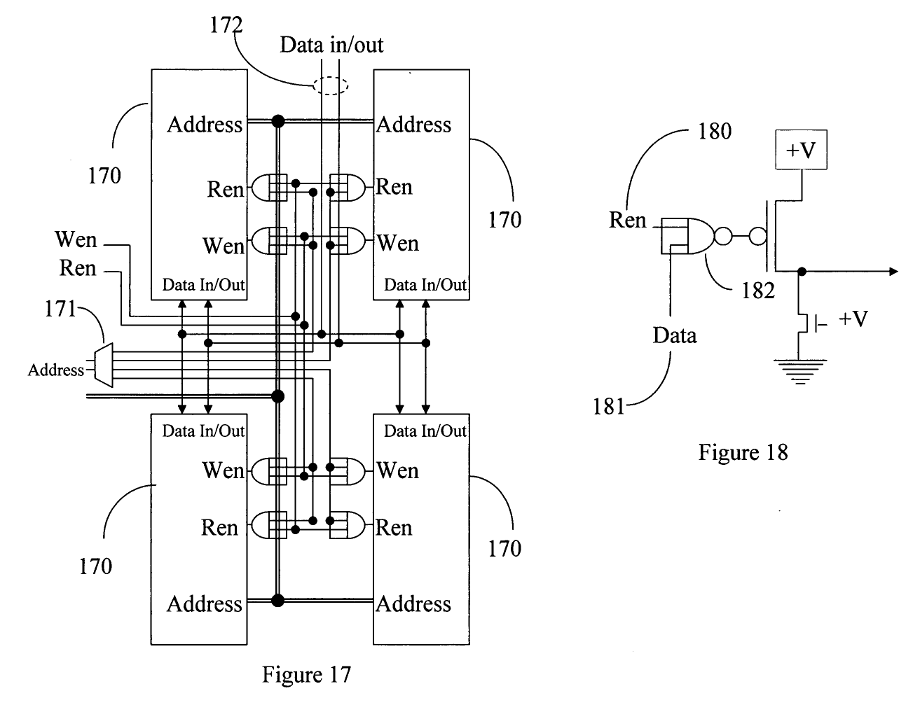

In another embodiment as shown in FIG. 17, the memory may be comprised of a number of sub-blocks 170 with separate address and core logic as shown in FIG. 4. Each of these sub-blocks is individually addressed as typically occurs by a decoder 171, separately enabling the Read or Write operations. The Data In/Out 172 of this composite memory is a combination of all the individual memories' Data In/Outs tied together. Test logic can be added at this level by replacing the decoder 171 with the decoder shown in FIG. 14, replacing each sub-block's 170 test mode latch as shown in FIG. 9, with one at the top level, and converting the tristate outputs 56, as shown in FIG. 5, with wired-OR drivers as shown in FIG. 18. The Ren signal 180 and the Data signal 181, from the MUX 55 shown in FIG. 5, are ANDed 182 together in FIG. 18 to drive a strong high level or a weak zero level. In this way if Ren is enabled and there is an error during test, the NAND 132 gate in FIG. 13 would be high, driving a high level out the respective Data Out line. In test mode, because all the sub-blocks 170 are enabled at the same time, this configuration would require no more tests than an individual sub-block memory test.

It also should be noted that the Address bit An 94 on FIG. 9 could be one of the address bit inputs to the MUX 171 shown in FIG. 17. The chosen bit must maintain a low value until the end of test mode, after which it can be raised high. As such, address testing or other miscellaneous tests can be done following the test mode testing, without having to power off the chip or block, but once out of test mode, for safe normal operation, the test mode can not be entered without powering off the memory and powering it up under the proper conditions.

The process of testing a memory that contains all the test logic constructs of this invention to maximize the test reduction, is as follows:
a) Bring up the memory in test mode,
b) Write a specific pattern to ½ of the memory,
c) Write the opposite pattern to the other V₂ of memory,
d) Read all of the first ½ of memory, observing the output for errors (1 levels),
e) Write the registers (using An as a clock) with the opposite pattern,
f) Read all of the second ½ of memory, observing the output for errors,
g) Repeat steps b through f for as many patterns as required,
h) Take the memory out of test mode,
i) Write into N memory locations unique values, where N =number of address bits, and
j) Read back the N locations, comparing the values for errors.

Of course the errors may be logged or the test may be stopped on the first error, but in either case the part must be tested without test mode on to determine the exact location and type of error.

It is contemplated that the techniques in the embodiments described in this patent are not limited to any level of width, depth, hierarchy or type of semiconductor read/write memory. As such it is further contemplated that the above techniques may be used in part or in whole depending on the configuration of memory they are applied to. It is also further contemplated that semiconductor read/write memories may be configured using different but logically equivalent types of structures, and that these techniques can be suitably modified by one well versed in the state of the art for such structures.

It is also contemplated that these techniques may be applied to in whole or in part with many of the other related memory test and repair techniques known in the industry.

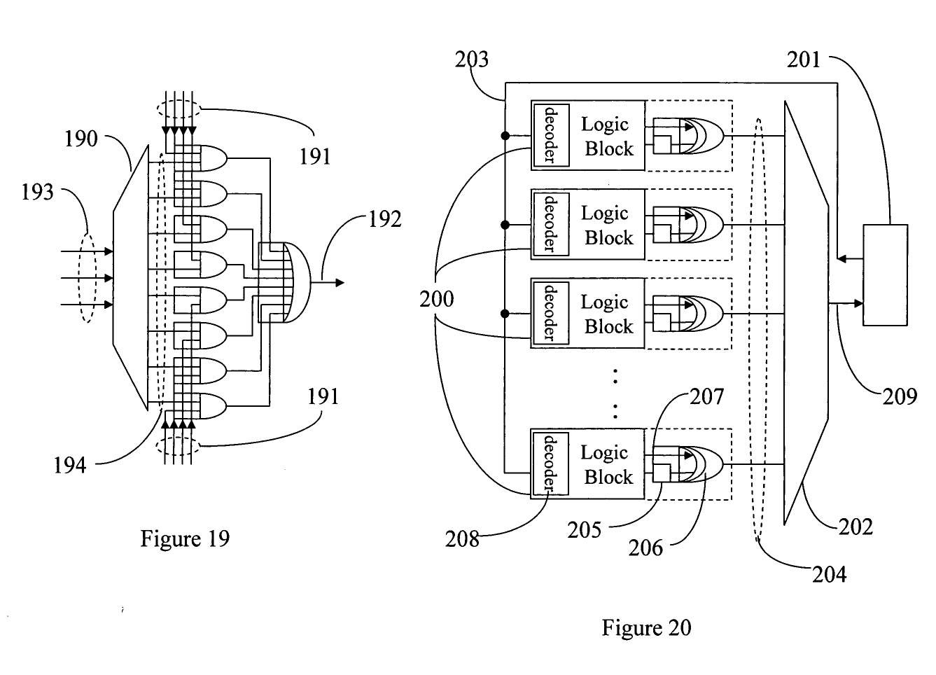

In addition these techniques may also be applied in whole or in part to the testing of non-memory structures. One such class of structures are wide MUXes, an example of which is shown in FIG. 19. Wide MUXes are used in communications structures such as switches and buses to select among a large number of lines to transfer data. In another case processor instruction units decode instructions, selecting from a potentially large set of possible instructions.

A further embodiment of this invention is illustrated using FIG. 19. Normally the address 193 is decoded through the decoder 190, which enables only one of its outputs 194 that, in turn, selects one of the input lines 191 to be transferred to the output 192. This structure has the limitation of blocking the values on all but the single selected input from getting to the observable output 192, at any given time. To adequately test such a structure, the decoder must be cycled through all of its addresses to detect the values on all of the input lines 191 before setting the next test pattern on the logic behind each input line. Applying the same memory techniques to the structure in FIG. 19, the decoder 190 is replaced with a decoder such as shown in FIG. 14. Now, while in test mode, all the decoder outputs 194 are enabled selecting all the input lines, and if all input lines' expected values are low the logic behind the input lines is tested in one pattern, thus reducing the number of patterns needed to test the logic behind the input lines 191. Of course, as with the memories, the substituted decoder can be put into normal mode when testing the input lines in the high state and the decoder itself.

As a result, these techniques can also be used on systems comprised of logic blocks, an example of which is shown in FIG. 20. On large integrated devices today it is not uncommon to have many logic blocks 200 that act as slaves on a common bus with a single master block 201. This master block 201 broadcasts to the inputs of all the other logic blocks on an output 203, and receives data from the outputs 204 of the logic blocks via a MUX 202. The output 203, which broadcasts both data and block addresses to the logic blocks 200, and the MUX 202 form the bus. The output 203 and input 209 to the master block are typically groups of many individual signals, as are the inputs to the logic blocks 200 and each of the logic block outputs 204. Each block selects data written to it by decoding the address from the master block output 203 with a decoder 208. Typically, each register within a block has a unique address, and, as such, a number of addresses may enable any given logic block to accept the associated data. The inventor has suggested in U.S. Pat. No. 6,687,865 that the master block 201 could be some form of processor, which can externally obtain or internally generate tests for each of the other logic blocks 200. If a test signal is added to the design and connected to the MUX 202, which is modified to use a decoder as shown in FIG. 14, the decoders 208 were modified as shown in FIG. 11, and an XOR 206 and a flip-flop 205 were added to the outputs of each logic block 200 in a fashion similar to the addition of the XOR 105 and flip-flop 102 added to memories, as seen in FIG. 10, the output 207 in FIG. 20 of the logic within each logic block would be exclusive-Ored with the contents of its flip-flop 205 to form the contents of the actual logic block outputs 204. Furthermore, for each logic block's decoder 208, when converted to the form shown in FIG. 11, the decoder must be extended such that one of the decoded outputs 113 can be used to select the added flip-flops. The address bits 111 should also be selected to allow broadcasting of similar input data to multiple logic blocks simultaneously, and the address bits 112 should be selected to distinguish between groups of logic blocks that require different input data.

The process of testing a device that contains all the test logic constructs of this embodiment of the invention, is as follows:
a) Bring up the device in test mode,
b) Write a specific pattern to the addressed logic blocks,
c) Write the expected values to addressed logic blocks flip-flops 205,
d) Repeat steps b and c until all data have been written,
e) Clock and read all of logic blocks simultaneously, observing the output for errors (1 levels),
f) Repeat steps b through e for as many patterns as required,
g) Take the device out of test mode,
h) Write zeros into all logic blocks' flip-flops 205,
i) Write logic block patterns and read each logic block output, checking results for errors, and
j) Repeat step i until normal mode selected logic has been tested.

Of course the errors may be logged or the test may be stopped on the first error, but in either case the part must be tested without test mode on to determine the exact location and type of error. Also step h is necessary because, when the device is put into normal mode, the contents of each logic block's flip-flop 205 determines the polarity of its output 204. Setting the flip-flops low ensures the logic output 207 is not inverted when it propagates to the block's actual output 204. Furthermore, if test mode is determined by an independently controlled signal that can be set or cleared at any time, the order of steps a through f and g through j may be reversed.

It is contemplated that the techniques in the embodiments described herein are not limited to any level of width, depth, hierarchy or type of semiconductor logic block and bus structure. As such it is further contemplated that the above techniques may be used in part or in whole, depending on the configuration of bus structure in the device. It is also further contemplated that on-chip buses may be configured using different but logically equivalent types of structures, and that these techniques can be suitably modified by one well versed in the state of the art for such structures. For example, it is not uncommon to have separate decodes in each logic block to both read data from and write data onto a tristate bus. This type of structure can be converted into a wired-OR bus, with suitably modified decoders.

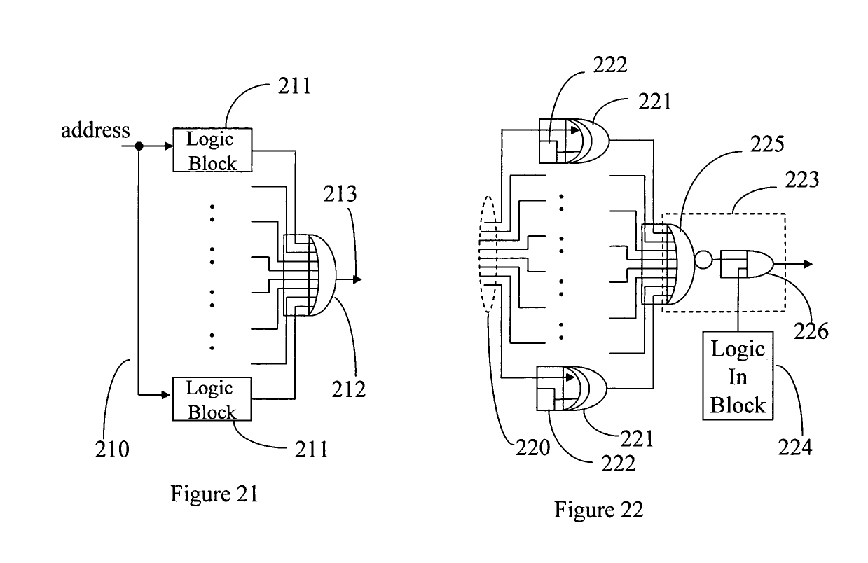

Furthermore, these techniques may also be applied to any structure that selects between a multiplicity of outputs via some form of address selection structure. One such structure is shown in FIG. 21, where a common address 210, is used to enable one of a multiplicity of logic blocks 211. An OR function 212 propagates the selected output to the output of the OR function 213. In this example the decode logic to select one of the logic block's outputs is distributed within each of the logic blocks. An example of such a structure is shown in FIG. 22. The address signals 220 are distributed to a multiplicity of XOR functions 221, which compare the address, bit by bit, with a pre-defined set of bit values that form the address of the logic block. These bit values may be stored in registers 222, or hardwired to the XOR functions 221. The results of the bit-by-bit comparison are used in some selection logic 223 to select the output of the logic in the block 224. The selection logic may comprise a NOR function 225 that combines the results of all the bit wide comparisons, and gates the output of the logic in the block 224 through an AND function 226. In this fashion each logic block is selected based on its address. As was stated at the beginning of this description, the resulting output 213 from all the logic blocks 211 in FIG. 21 need not be a bus. It could just be one or more signals being selected by the address 210.

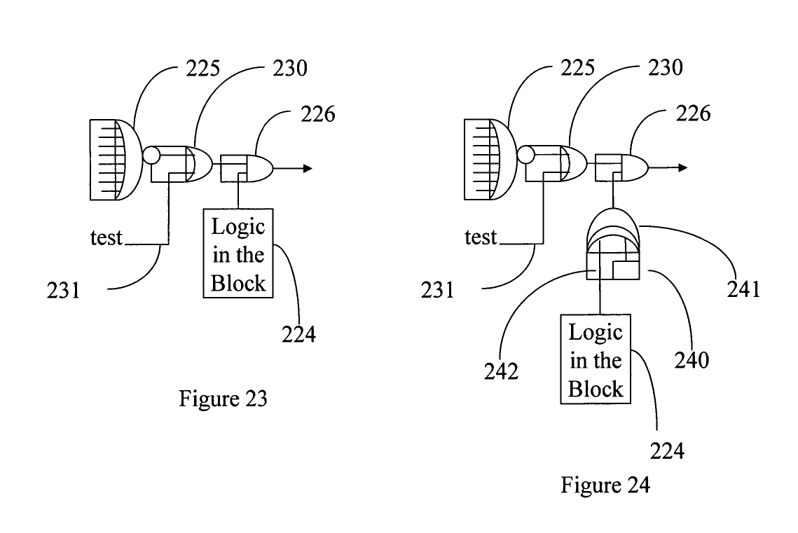

To test such logic requires individually selecting each logic block, and observing its output. On the other hand, the logic blocks can all be selected simultaneously, by modifying the selection logic shown in FIG. 22 to the form shown in FIG. 23. By inserting an OR function 230 between the NOR function 225 and the AND function 226, gated by a test signal 231, setting the test signal to a logical one level enables the AND function 226 to transfer the output of the logic in the block 224. Furthermore, as shown in FIG. 24, an XOR function 241, can compare the logic in the block's output 242 with the contents of a register 240, which as with the bus example, insures the correct values are simultaneously observed, and only failures are registered. Such registers may be part of a scan string which is loaded during scan testing, or may be loaded from other regular inputs of the logic block while in test mode, but in either case the test mode defined in the various embodiments of this patent need not be the test mode defined in other scan based testing methods.

A method to modify a design to accelerate its testing may consist of some or all of the following steps:
a) Define all groups of address signals,
b) Trace address signals to either comparison logic or decodes,
c) If a decode, replace it with a modified decode with test mode,
d) If comparison logic, insert a gate to override the comparison with test mode,
e) Determine the signals that are selected by either the comparison logic or decodes,
f) Add registers and XOR functions to the selected signals, such that the registers are enabled by a test mode,
g) Separately generate tests for each of the logic block's selected signals
h) Simulate the tests to obtain the selected signals expected values,
i) Organize the tests by iteratively grouping one test from each of the selected signals test for all the selected signals,
j) Translate each group of tests into vectors by
   1. Loading all expected values for all selected signals,
   2. Combining input values for all selected signals, and
   3. Creating a constant non error output vector,
k) Add signals to the translated vectors to put the part into test mode.

It will be appreciated by persons skilled in the art that the present invention is not limited by what has been particularly shown and described hereinabove. Rather the scope of the present invention includes both combinations and sub-combinations of various features described hereinabove as well as modifications and variations which would occur to persons skilled in the art upon reading the foregoing description and which are not in the prior art.

I claim:

1. A semiconductor memory comprising:
a plurality of memory cells forming a matrix wherein each row of memory cells is coupled to one of a plurality of word lines and each column of memory cells is coupled to one of a plurality of bit lines,
a plurality of memory address lines,
a memory address decoder enabling one of the multiplicity of said word lines,
a plurality of registers for capturing and setting states of said plurality of bit lines, and
test mode logic for selecting between normal operation mode and test mode of said memory,
wherein selecting said test mode allows a plurality of memory cells connected to a plurality of word lines to be written at the same time.

2. A semiconductor memory as in claim 1, wherein selecting said test mode enables the contents of each of a plurality of memory cells coupled to a common word line to be compared with the contents of each of the plurality of said registers to provide comparisons.

3. A semiconductor memory as in claim 2, wherein failures of said comparisons are made available outside of said memory.

4. A semiconductor memory as in claim 3, wherein said failures of said comparisons are combined and made available on fewer outputs than said plurality of said registers.

5. A semiconductor memory as in claim 1, wherein said memory address decoder selects one of said plurality of word lines during normal mode and selects more than one of said plurality of word lines during test mode.

6. A semiconductor memory as in claim 5, further comprising;
a plurality of Data in and Data out ports,
a signal for selecting between a read mode and a write mode, and
core address decode logic for selecting between said plurality of registers,
wherein in said write mode, said selected plurality of registers capture states on said Data in ports, and in said read mode, states of said plurality of said bit lines are captured by said plurality of registers, and states of said selected plurality of registers are transferred to said Data out ports.

7. A semiconductor memory as in claim 6,
wherein said core address decode logic selects all of said plurality of registers to write a repeating pattern of states from said Data input and Data out ports, and furthermore selects a combination of comparison results between a plurality of said registers and a plurality of said bit lines to be asserted onto said Data in and Data out ports when operating in said test mode.

8. A semiconductor memory comprising:
test mode logic for selecting between normal operation mode and test mode,
a plurality of memory sub-blocks, wherein each memory sub-block further comprises:
a plurality of memory cells forming a matrix, wherein each row of memory cells is coupled to one of a plurality of word lines and each column of memory cells is coupled to one of a plurality of bit lines,
a memory address decoder connected to said plurality of word lines,
a plurality of registers with sense and drive circuits, each of which is coupled to one of said plurality of bit lines,
a plurality of Data in and Data out ports, and
core address decode logic for selecting between said plurality of registers to write into and selecting between plurality of results from said bit lines to read from,
wherein in at least one setting said test mode logic enables a plurality of memory sub-blocks to be written into at the same time.

9. A semiconductor memory as in claim 8, further comprising:
address decode logic for selecting among memory sub-blocks,
wherein said address decode logic enables one of said plurality of memory sub-blocks to read from and to write into during normal mode of operation, and enables all of said plurality of memory sub-blocks to read from or write into during test mode.

10. A semiconductor memory as in claim 9, further comprising:
wired-OR I/O on each of a plurality of said Data in/out ports on each of a plurality of said memory sub-blocks, and
block Data In/Out ports that are connected to a plurality of said wired-OR I/O,
wherein the contents of each of a plurality of memory cells connected to a single word line are simultaneously compared with the contents of each of the plurality of registers to thus create comparisons, and wherein failures of said comparisons are combined and made available on the said wired-OR I/O for combining failure results of said plurality of said memory sub-blocks.

11. A semiconductor memory as in claim 1,
wherein at least one of said memory address lines is used as a clock signal to enable writing values into a plurality of said registers.

12. A semiconductor memory as in claim 1,
wherein at least one of said memory address lines is used as a reset signal to disable said test mode and enable operating said semiconductor memory in normal mode.

13. A semiconductor memory as in claim 1,
wherein enabling said test mode is achieved by setting a specific set of values on a specific set of control lines during power up.

14. A semiconductor device comprising:
a plurality of functional blocks,
a plurality of decoders, each with a plurality of outputs, and
test mode logic for selecting between normal operation mode and test mode of said decoders,
wherein in test mode said decoders enable a plurality of said decoders' outputs, and in normal mode said decoders enable one of said decoders' outputs.

15. A method for testing a semiconductor memory, said method comprising:
setting said memory into test mode,
said test mode enabling a plurality of addresses when writing, and enabling the comparison of internal read data with expected data and combining the results when reading,
repeatedly writing and reading a plurality of addresses simultaneously, while collecting results,
setting said memory into normal mode, said normal mode enabling a single address when writing and enabling providing the results from a single address when reading, and
repeatedly writing and reading a plurality of addresses serially to test decode logic.

16. A method of testing a semiconductor device that includes a plurality of functional blocks, the method comprising:
setting said device into test mode,
repeatedly writing patterns and expected results to, and reading comparison results from, a plurality of said functional blocks simultaneously,
setting said device into normal mode, said normal mode enabling single functional block reading, and
repeatedly writing patterns to, and reading results from, said functional blocks, one functional block at a time.

17. A method as in claim 16, wherein at least one functional block is a memory sub-block.

18. A method as in claim 16, wherein at least one functional block is a logic block.

19. A method as in claim 16, wherein each of said functional blocks includes an associated storage element, and wherein said step of writing expected results comprises writing said expected results to the storage elements associated with said plurality of said functional blocks.

20. A semiconductor device as in claim 14, wherein at least one of said plurality of functional blocks comprises a logic block.

21. A semiconductor device as in claim 14, wherein at least one of said plurality of functional blocks comprises a memory block.

22. A semiconductor device as in claim 14, wherein each of said plurality of functional blocks includes an associated memory element, said associated memory element used to store an expected value during test mode.

23. A semiconductor device as in claim 22, wherein each of said plurality of functional blocks further comprises a comparison device to compare said expected value with an output value of the functional block.

24. A method of testing a semiconductor device that includes a plurality of functional blocks, the method comprising:
setting said device into normal mode, said normal mode enabling single functional block reading,
repeatedly writing patterns to, and reading results from, said functional blocks, one functional block at a time,
setting said device into test mode, and
repeatedly writing patterns and expected results to, and reading comparison results from, a plurality of said functional blocks simultaneously.
